(19) United States
(12) Patent Application Publication
(10) Pub. No.: US 2021/0219383 A1
(43) Pub. Date: Jul. 15, 2021

(54) SYSTEM AND METHOD FOR POWERLINE MONITORING

(71) Applicant: Tricon Sales LLC, Seattle, WA (US)

(72) Inventors: Howard Gene Trott, Kirkland, WA (US); Kent Deric Eldredge, West Jordan, UT (US); Mark Alexander Thomas, Seattle, WA (US); Anand Rajaratnam, Seattle, WA (US); Katy McKenzie Richey, Seattle, WA (US); Adrian Men Gee Yip, Snohomish, WA (US); Gary Ray Gause, Camano Island, WA (US); Bryce Prestwich, Riverton, UT (US)

(21) Appl. No.: 17/147,998

(22) Filed: Jan. 13, 2021

Related U.S. Application Data
(60) Provisional application No. 62/960,600, filed on Jan. 13, 2020.

(51) Int. Cl. H04W 84/18; H04W 60/04; H04W 64/00; H04W 72/04

(52) U.S. Cl. CPC H04W 84/18; H04W 72/0413; H04W 64/006; H04W 60/04

(57) ABSTRACT

A series of sensors tags are designed to be attached to electric distribution lines and poles as well as high voltage transmission lines and towers. Each sensor tag contains an array of sensors that measure operational performance of the powerlines and supporting infrastructure and detect any anomalies in operation. The sensor tags also have wireless communication capability and communicate sensor data to a backhaul communication node. The backhaul communication node relays the sensor data, via cellular or satellite connection to a wide area network, such as the Internet. In one embodiment, performance data may be collected over a period of time and a profile established to indicate levels of normal operation and thresholds at which abnormal operation should be reported. If the sensor tag has a profile stored therein, it need only report sensor data when it exceeds some predetermined threshold defined in the profile.

### BACKGROUND OF THE INVENTION

### Field of the Invention

The present disclosure relates to electrical powerlines in general and, more specifically, to a system and method for detecting hardware, mechanical, and electrical failures and precursors to failure in electrical transmission and distribution systems through real-time monitoring of movement changes over time.

### Description of the Related Art

Powerlines are a critical element of the electrical grid. The health of these powerlines can be impacted by many factors, including:
1. A likely obstruction;
2. A mechanical failure or precursor to failure; and
3. A pole or tower has shifted, putting the integrity of the structure at risk.

Conventional methods for detecting failures and precursors to failure involve physical inspection by humans and more recently advances in SCADA and Light Detection and Ranging (LiDAR) technologies. Due to time, resource constraints and accessibility challenges, physical inspection by humans tends only to be done on an intermittent basis; often lines are inspected less than twice a year. SCADA and LiDAR technologies, while relevant to electric system monitoring and helpful to accelerating human-led inspection, have serious shortcomings including a dependence on electrical signature for insights (SCADA), moment-in-time limitations (LiDAR), as well as a general inability to pinpoint fault/failure location with precision (SCADA). When coupled with the more extreme weather patterns resulting from climate change, this lack of real-time asset monitoring capability on the part of utility operators increases the risk that a line-level failure with an unknown location has costly and devastating ramifications either due to a wildfire outbreak or extensive storm damage.

### BRIEF DESCRIPTION OF THE SEVERAL VIEWS OF THE DRAWING(S)

FIG. 1 illustrates an exemplary transmission system architecture in accordance with the present disclosure.

FIG. 2 illustrates an exemplary distribution system architecture in accordance with the present disclosure.

FIG. 3 is a functional block diagram of sensor tags configured in accordance with the present disclosure.

FIG. 4 is a functional block diagram of a backhaul communication node configured in accordance with the present disclosure.

FIG. 5 is a flowchart illustrating the operation of the sensor tags of FIG. 2.

### DETAILED DESCRIPTION OF THE INVENTION

The present disclosure describes a system and method that detects failures and precursors to failure in transmission and distribution powerlines. One indicator of asset health is a change in movement behavior of the powerline, which can be tracked via a suite of sensors including a 3-axis accelerometer, barometric pressure gauge, and line and ambient temperature gauges, installed between sets of distribution and transmission poles and towers. As will be described in greater detail, a series of sensors are positioned to monitor barometric pressure, ambient and line temperature, as well as movement and vibration on each powerline segment between poles or towers and also on some powerline poles and towers. A profile of those sensor readings is developed for each sensor, with GPS location measurements taken at install. More particularly, the sensors are all calibrated to a common standard (e.g., sea level) prior to installation. Thus, the height of the sensors relative to the poles and towers is fixed and known. By observing the fluctuation from the measurements in the sensors on the powerlines compared to other sensors on other lines in the same pole to pole segment we can determine changes in movement that indicate faults, failures or precursors to failure with location precision. Specifically, the process described herein relates to a novel technique to identify segments of the powerline that are in need of inspection and/or maintenance without requiring physical inspection. The following elements are used as part of the overall system.

Elements

Sensor Tags.

These tags comprise a collection of sensor elements that are installed on transmission and distribution lines between pole and tower segments. Those skilled in the art will appreciate that some conventional monitoring systems use electrical power induced from the powerlines and thus cannot operate when the powerlines are depowered, which in the age of utility-controlled public power shut-offs (due to wildfire) and widespread outages resulting from massive storm damage, is increasingly common. In contrast, the sensor tags described herein are powered by batteries that allow them to transmit and receive updates for over 15 years and also allow for data collection and transmission when powerlines are depowered, providing operators with readings to assess asset risk in real-time, during an emergency and throughout power restoration periods.

The sensor tags' inclusion of a 3 axis accelerometer and/or gyro sensor aids in the determination of precision changes in movement and permits the system to understand if the line is swinging or static or vibrating when the barometric pressure and temperature measurements are taken.

A transceiver provides a wireless link between the sensor tags and a backhaul communication node placed up to two miles away. In one embodiment, the transmitter is configured for operation in accordance with IEEE 802.15.4. However, other low power transceivers can be used satisfactorily with the system 100. The system 100 is not limited by the particular form of the wireless communication with the sensor tags. In yet another exemplary embodiment, the sensor tags can communicate directly with a satellite using a satellite link. This embodiment can eliminate the need for the backhaul communication node.

Over time a profile is developed based on the behavior of a particular line relative to similar lines in the system. A combination of factors including line location, line size, line current, line voltage, line tension, temperature, seasonality, wind speed and direction, and relative humidity contribute to the profile. Situational measurements are documented at or prior to install and risk thresholds are set relative to the installation specifications. That profile is sent to the individual sensor tags and is used to define the thresholds of normal movement. Once a profile is set, the sensor tags can monitor operation and report data only when an anomaly is detected. In addition, the sensor tags can report data periodically to confirm that the device is operational. Either way, the number of transmissions required by the sensor tags are greatly reduced and thus battery capacity is conserved.

Backhaul Communication Node.

The overall system includes a number of backhaul communication nodes. The backhaul communication nodes can be placed on poles or towers at intervals along the transmission and distribution pathways. The backhaul communication nodes collect information from a number of sensor tags over varied distances and transmit that data either via cellular or satellite to the cloud for monitoring by operators. These backhaul communication nodes are powered by solar panels and have a rechargeable battery. If the solar panel is damaged, the backhaul communication nodes can still receive signals from tags and transmit data for 2 weeks. The backhaul communication nodes can also report the damage to the solar panel.

Pole/Tower Tags.

These tags are sensors installed on poles or towers themselves, or on equipment sitting on the poles or towers (e.g. transformers), rather than the powerlines. The pole/tower Tags are powered by batteries that allow them to transmit updates for over 15 years and also allow for data collection and transmission when powerlines are depowered. As noted above, conventional systems that induce power from the powerlines cannot operate when the powerline is depowered. Each pole/tower Tag utilizes directional antennae to wirelessly transmit sensor data to the backhaul communication nodes placed up to two miles away, as described above with respect to sensor tags and backhaul communication nodes. The pole/tower Tags also have a 3 axis accelerometer. The accelerometer provides data necessary to understand with precision changes in movement needed to determine if the pole/tower is swinging or static or vibrating.

Patterns and Libraries.

As will be described in greater detail below, the Patterns and Libraries provide a historic operational profile used to define the normal/expected movement range and the patterns that define the changes in behavior that represent different types of anomalies.

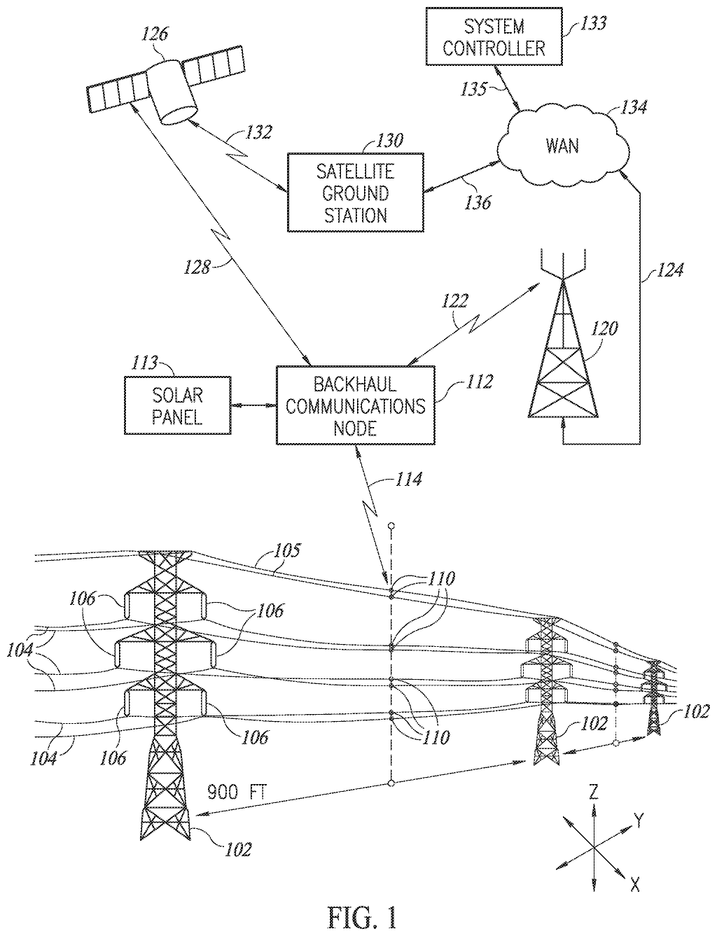

FIG. 1 illustrates an exemplary architecture of the transmission portion of a system 100. FIG. 1 illustrates transmission towers 102 and power transmission lines 104 connected thereto. In an exemplary embodiment, the transmission towers 102 are spaced apart at approximately 900 foot intervals. The transmission lines 104 are connected to the transmission tower 102 via insulators 106. The dimensions of the insulators 106 typically depend on the electrical voltage being carried on the transmission lines 104. At the top-most portion of the transmission towers 102, a pair of non-current carrying ground (or neutral) lines 105 may be installed for electrical safety purposes.

FIG. 1 also illustrates sensor tags 110 attached to each of the transmission lines 104 as well as each of the neutral lines 105. The operation of the sensor tags 110 will be described in greater detail below. The sensor tags 110 are wirelessly coupled to a backhaul communication node 112 via a wireless link 114. Each sensor tag 110 has its own wireless link 114 with backhaul communication node 112. In one embodiment, the backhaul communication node 112 is powered by a solar panel 113. As previously described, the backhaul communication node 112 can be mounted on the transmission tower 102 at intervals along the powerline pathway. However, for the sake of clarity, the backhaul communication node 112 is illustrated in FIG. 1 as a standalone installation.

Although FIG. 1 illustrates only a single backhaul communication node 112, the system 100 includes a plurality of backhaul communication nodes 112 dispersed generally along the power transmission line pathway so that all sensor tags 110 are within wireless communication range of at least one backhaul communication node 112.

The backhaul communication node 112 collects sensor data from the sensor tags 110 that are up to two miles away via the wireless link 114. In turn, the backhaul communication node 112 relays the sensor data via various forms of wireless communication. As illustrated in FIG. 1, a cell tower 120 may be in communication range of the backhaul communication node 112 via a cellular link 122. Alternatively, the backhaul communication node 112 can communication with a satellite 126 via a satellite link 128.

The satellite 126 relays the data to a satellite ground station 130 via a satellite ground station link 132. In turn, the satellite ground station 130 can send the collected data to a wide area network (WAN) 134, such as the Internet via a WAN link 136. Those skilled in the art will appreciate that the WAN link 136 may be implemented as a wireless link, hardwired link, optical link, or the like, or a combination thereof. The system 100 is not limited by the particular technology used to implement the WAN link 136.

Similarly, the cell tower 120 relays data from the backhaul communication node 112 to the WAN 134 via a cellular WAN link 124. As with the WAN link 136, the cellular WAN link 134 may be implemented by a combination of one or more known communications technologies. The system 100 is not limited by the specific form of the cellular WAN link 124. Although not illustrated in FIG. 1, the cell tower 120 communicates with a cellular core network. The connection from the cellular core network to the WAN 136 is typically implemented using a gateway server/router (not shown). These cellular connections are known in the art and need not be described in greater detail herein.

FIG. 1 also illustrates a system controller 133 coupled to the WAN 143 via a communication link 135. The system controller 133 is typically a server computer controlled by the power service provider. The system controller 133 receives and analyzes the sensor data provided by the sensor tags 110 to thereby monitor the overall health of the power grid. The system controller 133 can generate alarms to the power service provider to initiate powerline repairs or even shut down power in the event of a catastrophic failure, such as a downed transmission line 104. As will be described in greater detail below, the system controller 133 also provides machine learning capability to monitor incoming sensor data and adjust thresholds for reporting abnormal conditions.

FIG. 1 also illustrates a set of axes to illustrate powerline movements in different directions. For example, swaying movement of the power transmission lines 104 back and forth can be detected by displacement along the X-axis while galloping powerlines can be detected by displacement along the Y-axis and Z-axis. Sagging powerlines can be detected by displacement along the Z-axis.

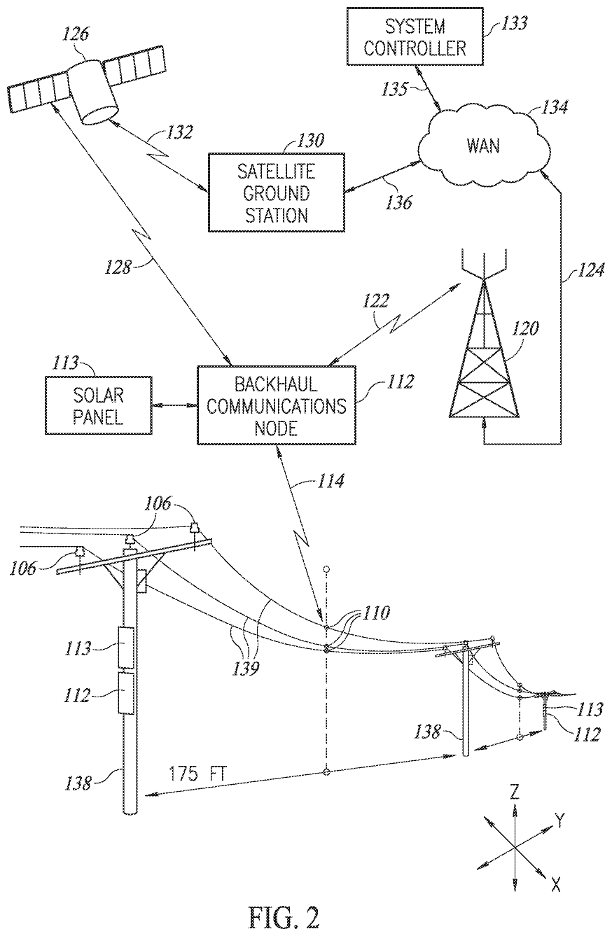

FIG. 2 illustrates an exemplary architecture of the power distribution portion of the system 100. FIG. 2 illustrates power poles 138 instead of the transmission towers 102 of FIG. 1. The power poles 138 are often wooden poles that are much shorter in height and are typically placed closer together than the transmission towers 102 of FIG. 1. In an exemplary embodiment, the power poles 138 are spaced apart at approximately 175 foot intervals.

FIG. 2 also illustrates power distribution lines 139 connected to the power poles 138 via insulators 106. As noted above, the dimensions of the insulators 106 typically depend on the electrical voltage being carried on the transmission lines 104. Because the operating voltage of the power distribution lines 139 are much lower than the operating voltage of the power transmission lines 104, the insulators illustrated in FIG. 2 are smaller in size than the insulators 106 in FIG. 1.

FIG. 2 also illustrates sensor tags 110 attached to each of the power distribution lines 139. The operation of the sensor tags 110 is generally identical to the sensors attached to the power transmission lines 104. However, the detection thresholds and sensor profiles will be different from those sensors attached to the power transmission lines 104. The communication infrastructure between the sensor tags 110 and the WAN 134 also include the backhaul communication node 112, solar panel 113, wireless links 114, cell tower 120, satellite 126, ground station 130 and the various communication links described above with respect to FIG. 1. For the sake of brevity, those components need not be described again. FIG. 2 also illustrates a set of axes to illustrate powerline movements in different directions in the same manner as described with respect to FIG. 1.

FIG. 2 also illustrates the system controller 133 coupled to the WAN 143 as described with respect to FIG. 1. In this aspect the system controller 133 the same functions to receive and analyze sensor data to thereby monitor the overall health of the distribution portion of the power grid. The system controller 133 can generate alarms to the power service provider to initiate powerline repairs or even shut down power in the event of a catastrophic failure, such as a downed power distribution line 139. The system controller 133 also provides machine learning capability to monitor incoming sensor data and adjust thresholds for reporting abnormal conditions. Those skilled in the art will appreciate that the thresholds in the power distribution portion of an electrical power grid, such as illustrated in FIG. 2, will differ from the thresholds in the power transmission portion of an electrical power grid illustrated in FIG. 1.

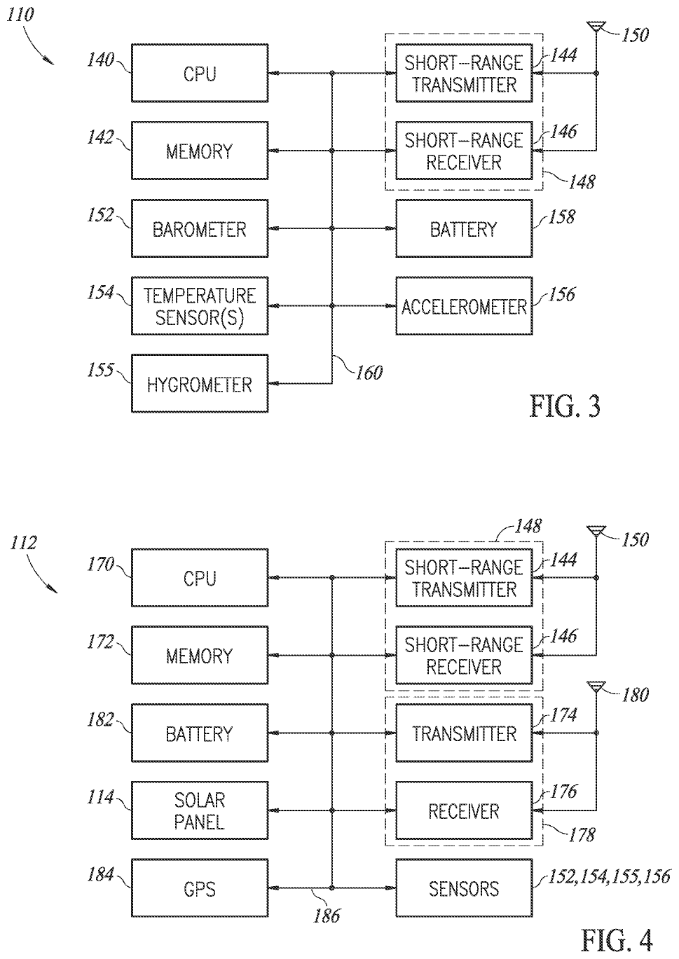

FIG. 3 is a functional block diagram illustrative of one of the sensor tags 110 illustrated in FIGS. 1 and 2. Each sensor tag 110 includes a central processing unit (CPU) 140. Those skilled in the art will appreciate that the CPU 140 may be implemented as a conventional microprocessor, application specific integrated circuit (ASIC), digital signal processor (DSP), programmable gate array (PGA), or the like. The sensor tag 110 is not limited by the specific form of the CPU 140.

The sensor tag 110 in FIG. 3 also contains a memory 142. In general, the memory 142 stores instructions and data to control operation of the CPU 140. The memory 142 may include random access memory, ready-only memory, programmable memory, flash memory, and the like. The sensor tag 110 is not limited by any specific form of hardware used to implement the memory 142. The memory 142 may also be integrally formed in whole or in part with the CPU 140.

The sensor tag 110 of FIG. 3 also includes a transmitter 144 to enable communication with the backhaul communication node 112 (see FIG. 1). FIG. 3 also illustrates a receiver 146 that operates in conjunction with the transmitter 144 to communicate with the backhaul communication node 112. In a typical embodiment, the transmitter 144 and receiver 146 share circuitry and are implemented as a transceiver 148. The transceiver 148 is connected to an antenna 150. The transceiver 148 is illustrated as a generic transceiver. In an exemplary embodiment, the transceiver 148 is implemented in accordance with IEEE 802.15.4. Other forms of low-power transceivers may also be used to implement the transceiver 148. In operation, the transceiver 148 in each sensor tag 110 transmits sensor data to a nearby backhaul communication node 112. The backhaul communication node 112 transmits an acknowledgement message to each sensor tag 110 in response to receiving the sensor data. As will be discussed in greater detail below, the backhaul communication node 112 also transmits updated profile data to each sensor tag 110 and can also transmit updated software to each sensor tag 110.

Each sensor tag 110 is equipped with multiple sensors that provide desired sensor data. In one embodiment, the sensor tag 110 includes a barometer 152, one or more temperature sensors 154, a hygrometer 155, and an accelerometer 156. The barometer 152 for each sensor tag 110 may be calibrated at sea level so that each barometer has the same reading prior to installation on the transmissions lines 104 and distribution lines 139. Following installation, each barometer 152 will accurately measure the height above sea level. In an exemplary embodiment, the barometer 152 is a commercially available component that is accurate to within ±2 inches.

As will be described in greater detail below, the backhaul communication node 112 is also equipped with sensors, such as the barometer 152 and the temperature sensor 154 to provide reference measurements. For example, all barometers 152 are calibrated at sea level. The height of the backhaul communication node 112 is measured at the time of installation and thereby provides a reference pressure measurement. As each sensor tag 110 is installed, the pressure measurement provided by the barometer 154 in the sensor tag can be compared to the reference pressure measurement to determine the height of the sensor tag relative to the known height of the backhaul communication node 112.

One or more of the temperature sensors 154 can measure the temperature of the power transmission line 104 (see FIG. 1) or the power distribution line 139 (see FIG. 2) to which it is attached due to an infrared sensor focused on the line. Another of the temperature sensors 154 can measure the environmental temperature. Additionally, the system 100 uses GPS to get a base elevation at install and evaluates line height and temperature fluctuations with pressure sensor and barometer, on a tag by tag basis. As those skilled in the art will appreciate, the transmission lines 104 will droop as the environmental temperature increases. That is, the transmission lines 104 will droop more when the outside temperature is 100° F. than they will when the outside temperature is 50° F. Temperature measurement of the individual power transmission lines 104 or power distribution lines 139 can indicate if the powerlines are overheating or overenergized. Those skilled in the art will appreciate the transmission lines 104 will droop as the temperature of the transmission line itself increases. It is critical that operators closely monitor droop as changes in resonate frequency lead to increased risk of line interference with each other or with nearby objects, namely phase to phase, galloping, and vegetation.

The accelerometer 156 measures precise timing of movement of the sensor tag 110. In an exemplary embodiment, the accelerometer 156 is a 3-D accelerometer. The accelerometer 156 provides an indication of movement of the sensor tag 110 during height measurements. The danger of powerline movement is the potential for interference or asset fatigue-induced failures. For example, movement that results in greater sag could lead to phase-to-phase sparking activity; or a line could come into contact with vegetation causing an ignition; or a tree could fall into a line causing a powered line to hit the ground resulting in human electrocution. Changes in line position relative to adjacent line can be a significant problem and, when coupled with other data points, can be used by the system 100 to pinpoint fault/failure causation.

The sensor tag 110 also includes a battery 158, which has sufficient capacity to operate the sensor tag 110 for 15 years. The long battery life assures satisfactory operation without the difficult maintenance costs of frequent battery replacement.

The various components illustrated in FIG. 3 are coupled together by a bus system 160. The bus system may include an address bus, data bus, power bus, control bus, and the like. For the sake of convenience, the various busses in FIG. 3 are illustrated as the bus system 160.

The pole/tower tags operate in a manner similar to the operation of the sensor tags 110 attached to powerlines. The pole/tower tags have many of the same components as the sensor tags 110, such as the CPU 140, memory 142, and transceiver 148. In addition, as noted above, the pole/tower tags also have the battery 158. The pole/tower tags also have some sensors, such as the accelerometer 156. However, the pole/tower tags may not require a full array of sensors. Those skilled in the art will appreciate that the particular sensors in the pole/tower tags are designed to elicit data regarding the performance or operational status of the pole/tower. The accelerometer 156 is used to detect movement of the pole/tower. For example, loose connections on the tower are detected by the accelerometer 156 and may indicate an imminent failure of the tower. Furthermore, in extremely high winds the accelerometer 156 may indicate that the tower is swaying in the wind. Similarly, a car could hit a distribution pole causing a live conductor to hit the ground and the accelerometer 156 would indicate immediate attention is needed.

The sensor tags 110 may also be used to monitor operating conditions in other parts of a power grid. With respect to the power transmission system illustrated in FIG. 1, sensor tags 110 can be mounted directly on the transmission towers 102 and used to detect vibration, movement or other parameters that are indicative of abnormal operation of the transmission tower. For example, increased vibrations may be indicative of a loose bolt on the transmission tower 102. Similarly, sensor tags 110 can be mounted in a transformer vault or sub-station to monitor operation of transformers. A sudden movement detected by the accelerometers 156 can indicate a transformer failure while detected vibrations may indicate an imminent failure.

Similarly, the sensor tags 110 may also be used to monitor operating conditions in the power distribution system illustrated in FIG. 2. Sensor tags 110 can be mounted on each of the power poles 138 to monitor the condition of the pole. For example, power poles 138 are often wooden poles and may have support or guy wires to stabilize the pole. As the condition of the pole diminishes due to wood rot, erosion, or ground movement, for example, the sensor tag 110 may detect increased vibrations. In a power distribution system, transformers are often mounted directly to the power pole 138. A sensor tag 110 can be mounted directly to the transformer to monitor operation thereof.

FIG. 4 is a functional block diagram of the backhaul communication node 112 illustrated in FIG. 1. Each sensor tag 110 includes a central processing unit (CPU) 170. Those skilled in the art will appreciate that the CPU 170 may be implemented as a conventional microprocessor, application specific integrated circuit (ASIC), digital signal processor (DSP), programmable gate array (PGA), or the like. The backhaul communication node 112 is not limited by the specific form of the CPU 170.

The backhaul communication node 112 in FIG. 4 also contains a memory 172. In general, the memory 172 stores instructions and data to control operation of the CPU 170. The memory 172 may include random access memory, ready-only memory, programmable memory, flash memory, and the like. The backhaul communication node 112 is not limited by any specific form of hardware used to implement the memory 172. The memory 172 may also be integrally formed in whole or in part with the CPU 170.

The backhaul communication node 112 of FIG. 4 also includes a short-range transmitter 144 to enable communication with the sensor tags 110 (see FIG. 1). FIG. 2 also illustrates a short-range receiver 146 that operates in conjunction with the transmitter 144 to communicate with the sensor tags 110. In a typical embodiment, the transmitter 144 and receiver 146 share circuitry and are implemented as a transceiver 148. The transceiver 148 is connected to an antenna 150. The transceiver 148 is illustrated as a generic transceiver that is compatible with the transceiver 148 in the sensor tags 110. The transceivers 148 in the sensor tags 110 and the transceiver 148 in the backhaul communication node 112 are configured for compatible operation with each other no matter what physical device is used for implementation of the short-range transmitters. In an exemplary embodiment, the transceiver 148 is implemented in accordance with IEEE 802.15.4. Other forms of low-power transceivers may also be used to implement the transceiver 148. Operation of the transceiver 148 and the antenna 150 for communication between the sensor tags 110 and the backhaul communication node 112 is well-known in the art and need not be described in greater detail herein.

The backhaul communication node 112 of FIG. 4 also includes a transmitter 174 to enable the relay of data received from the sensor tags 110 (see FIG. 1). FIG. 4 also illustrates a receiver 176 that operates in conjunction with the transmitter 174 to relay communications between the sensor tags 110 and the WAN 134. In a typical embodiment, the transmitter 174 and receiver 176 share circuitry and are implemented as a transceiver 178. The transceiver 178 is connected to an antenna 180.

The transceiver 178 is illustrated as a generic transceiver. As illustrated in FIG. 1, the backhaul communication node 112 is configured for communication with the cellular tower 120 or the satellite 126. Accordingly, the transceiver 178 is configured for cellular communication or for satellite communication. Alternatively, the backhaul communication node 112 could include transceivers for both cellular communication and satellite communication. Other forms of known communication links, including a conventional radio transceiver (e.g., GPRS), microwave, hardwired communication link, and the like, may be used alone or in combination to implement the transceiver 178.

The backhaul communication node 112 also includes a battery 182, which has sufficient capacity to operate the backhaul communication node for at least two weeks. The solar panel 113, shown in FIGS. 1-2, recharges the battery 182 in the backhaul communication node 112.

The backhaul communication node 112 can include any or all of the sensors described above with respect to the sensor tags 110. This includes sensors, such as the barometer 152, the temperature sensor 154, hygrometer 155, and the accelerometer 156. For convenience, FIG. 4 illustrates the various sensors as a single block.

The backhaul communication node 112 also includes a GPS receiver 184. The GPS receiver 184 can provide precise time and location data, including the height, of the backhaul communication node 112. However, those skilled in the art will appreciate that other satellite-based location determining technologies can be used in place of the GPS receiver 184.

The barometer 152 provides a reference pressure measurement that can be used to accurately determine the height of the sensor tags 110, at the time of installation, relative to the height of the backhaul communication node 112.

The barometer 152 and temperature sensor 154 may also provide reference data during operation of the system 100. For example, the barometer 152 on the sensor tag 110 will provide data related to changes in barometric pressure. However, the pressure changes may be due to changes in the height of the powerline, but may also be due, in part, to changes in ambient pressure as weather patterns change. The reference pressure measurement provided by the barometer 152 in the backhaul communication node 112 can be used to compensate for fluctuations in ambient pressure relative to the measurement provided by the sensor tag(s) 110.

Similarly, the temperature sensor 154 can provide a reference temperature measurement of ambient temperature away from any influence of the powerlines. As noted above, at least one temperature sensor 154 in the sensor tag 110 is configured to measure the temperature of the powerline itself. Other temperature sensors 154 in the sensor tag 110 may provide a measure of ambient temperature, but may be influenced by high temperatures in the powerline. Thus, the reference temperature measurement provided by the temperature sensor 154 in the backhaul communication node 112 can compensate for any influence of powerline temperature inadvertently measured by the ambient temperature sensor 154 in the sensor tag 110.

The various components illustrated in FIG. 4 are coupled together by a bus system 186. The bus system may include an address bus, data bus, power bus, control bus, and the like. For the sake of convenience, the various busses in FIG. 4 are illustrated as the bus system 186.

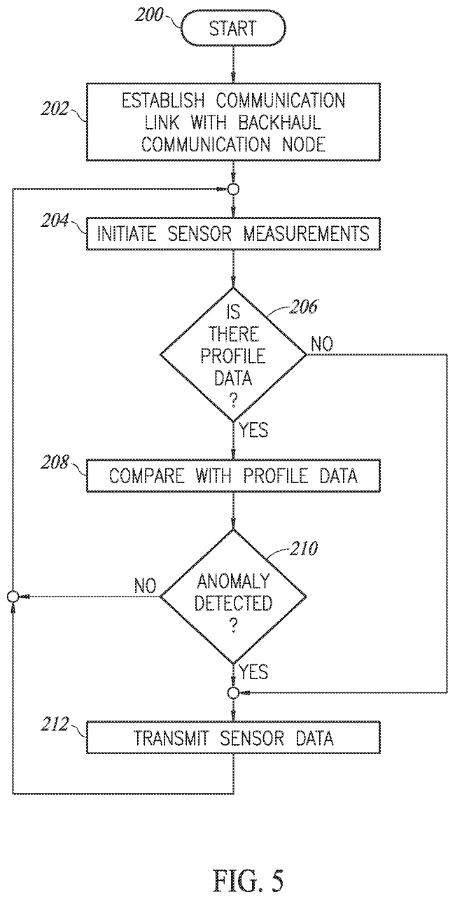

A flow chart in FIG. 5 illustrates an example operation of the sensor tag 110. At a start 200, the sensor tag is installed on a power transmission line 104 (see FIG. 1) or a power distribution line 139 (see FIG. 2). In step 202, the sensor tag 110 establishes a wireless communication link (e.g., the wireless communication link 114 of FIGS. 1-2) with the backhaul communication node 112. In step 204, the sensor tag 110 initiates sensor measurements. In the exemplary embodiment illustrated herein, this includes temperature measurements, barometric measurements, humidity measurements, and accelerometer measurements. Other sensors can be incorporated into the sensor tags 110.

In decision 206, the sensor tag 110 determines whether there is profile data stored within the sensor tag. If there is no stored profile data, the result of decision 208 is NO and in step 212, the sensor tag 110 transmits the sensor data to the backhaul communication node 112 (see FIG. 1). If profile data is stored in the sensor tag 110, the result of decision 206 is YES. In that event, in step 208, the sensor tag 110 compares the sensor measurements from step 204 with the stored profile data to detect any possible anomaly.

In decision 210, the sensor tag 110 determines whether an anomaly is detected. This would typically be a sensor measurement that exceeds some predetermined threshold stored within the profile data. If no anomaly is detected, the result of decision 210 is NO and the process returns to step 204 to initiate another round of sensor measurements. If an anomaly is detected, the result of decision 210 is YES. In that event, the sensor tag 110 transmits the sensor data to the backhaul communication node 112 (see FIG. 1) in step 212. Following the transmission of the sensor data in step 212, the process returns to step 204 to initiate a new round of sensor measurements.

Thus, the sensor tag 110 transmits all sensor data to the backhaul communication node 112 if the sensor tag does not yet have profile data. As sufficient amounts of data indicating normal operation are collected with respect to each sensor tag 110, a profile is established. Once the profile data is established, it may be transmitted, via the backhaul communication node 112 to each sensor tag and stored therein. Alternatively, the sensor tag 110 may be pre-loaded with profile data collected by the system 100 based on data generated by other sensor tags 110 under similar installation and environmental conditions. The development and use of profile data will be described in greater detail below. Once the sensor tag has profile data, it need only transmit sensor data in the event that the measurements indicate an anomaly. This approach saves battery power because it does not require transmission of data at the end of each cycle of sensor measurements.

Those skilled in the art will appreciate that variations can be readily implemented with respect to the flow chart of FIG. 5. For example, the flow chart illustrates a continuous cycle of sensor measurements. However, a time delay may be built into the measurement process so that measurements are performed periodically. For example, a measurement may be performed every few seconds or minutes rather than on a continuous basis. In addition, as noted above, the sensor tags 110 include the capability of bidirectional communication with the backhaul communication node 112. In addition to downloading the profile data, as described above, the backhaul communication node 112 may, for example, send a command to an individual sensor tag 110 or group of sensor tags 110 to initiate a measurement cycle. In response to the measurement cycle, the sensor tag(s) 110 may obtain sensor measurements and transmit the sensor measurement data in response to the command irrespective of whether or not a profile is stored in the sensor tag. This measurement data can be used to confirm satisfactory operation of the sensor tags, and may also be used in an emergency situation where updated data is required irrespective of any anomaly.

In yet another alternative embodiment, the sensor tags 110 can be configured to periodically transmit data to the backhaul communication node 112. For example, the sensor tag 110 can transmit sensor data as a “heartbeat” signal every 30 minutes, or some other selected time interval, to demonstrate that the sensor tag 110 is still operational. If a particular sensor tag 110 fails to send data to the backhaul communication node 112 for a time period that exceeds the selected heartbeat time interval, the backhaul communication node can report the sensor tag 110 status as inoperative. The power company can initiate the process of replacing the faulty sensor tag 110.

In the event of a temporary outage of the wireless links 114, each of the sensor tags 110 can temporarily store all measurement data locally within the memory 142 (see FIG. 3). When communications are restored, the sensor tags 110 can transmit the stored data to the backhaul communication node 112 in the manner described herein. Similarly, the sensor tags 110 can locally store data in the event of a failure of the backhaul communication node 112 itself. Each of the sensor tags 110 can temporarily store all measurement data locally within the memory 142. When backhaul communication node 112 becomes operational again (e.g., it is reset, repaired, or replaced), the sensor tags 110 can transmit the stored data to the backhaul communication node in the manner described herein.

The system 100 also incorporates a degree of communication redundancy to compensate for a failure of a communication link. For example, if the backhaul communication node 112 has failed, it will not transmit the acknowledgement message to the sensor tag 110 in response to receiving sensor data. If the sensor tag 110 does not receive the acknowledgement message within a predetermined timeout period, it can be assumed that the communication link 114 between the sensor tag 110 and the backhaul communication node 112 is inoperative.

In the event of a failed communication link 114, the sensor tag 110 will transmit a link request to other nearby sensor tags 110 to establish a communication link therewith. The sensor data will be sent to one or more of the nearby sensor tags 110. In turn, the nearby sensor tags 110 will relay the sensor data to other nearby sensor tags in a form of mesh network until the sensor data is received by one of the sensor tags 110 that is in communication with one of the backhaul communication nodes 112. The system 100 is capable of relaying sensor data through multiple sensor tags 110 up and down power transmission lines 104 or power distribution lines 139 until it reaches a sensor tag that has a working communication link 114 with a backhaul communication node 112. When communications are restored with the failed backhaul communication node 112, communications can be restored to normal operation as discussed above.

Profile Data.

As described above, the Patterns and Libraries provide a historic operational profile used to define the normal/expected movement range and the patterns that define the changes in behavior that represent different types of anomalies.

Upon initial installation of the system 100 there may be no profile data in existence. Threshold data may be experientially developed based on basic knowledge of power transmission and distribution systems. Initial data thresholds can be established for temperature, barometric and accelerometer reading.

For example, a pressure change in the sensor tag 110, with respect to a reference pressure measurement in the backhaul communication node 112, indicating a height change of the powerline that exceeds one foot may be set as a threshold for reporting an abnormal condition. In addition to this pressure threshold, a selected pressure change over a selected period of time may also be selected as another pressure threshold for reporting an abnormal condition. For example, a pressure change of 0.5 millibars in a time interval of 60 seconds may be set as a threshold for reporting an abnormal condition irrespective of the ambient pressure. Thus, the system 100 can accommodate multiple different thresholds for reporting abnormal conditions. Those skilled in the art will appreciate that other pressure thresholds are also possible with the system 100.

Similarly, a powerline temperature increase of 5° F. above ambient temperature may be set as a threshold for reporting an abnormal condition. In addition to this temperature threshold, a selected temperature increase over a selected period of time may also be selected as another temperature threshold for reporting an abnormal condition. For example, a powerline temperature increase of 5° F. in a time interval of 60 seconds may be set as a threshold for reporting an abnormal condition irrespective of the ambient temperature. Thus, the system 100 can accommodate multiple different thresholds for reporting abnormal conditions. Those skilled in the art will appreciate that other temperature thresholds are also possible with the system 100.

In another example, initial thresholds for the accelerometer may be set at a force of 1G. That is, any detected force in any of the three dimensions that exceeds 1G will result in the reporting of an abnormal condition. As with the barometer 152 and temperature sensor 154, the accelerometers 156 may also have multiple thresholds.

Table 1 below provides examples of sensor measurements that correspond to abnormal powerline conditions or abnormal conditions in the transmission or distribution systems of an electrical power grid. The axis coordinate system is illustrated in FIGS. 1 and 2.

TABLE 1
Error Conditions

| | |
|---|---|
| Line Drop | (Swift increase in barometric pressure, sizeable Z-axis |
| | movement) |
| Galloping | (increased size and frequency of movement on the |
| lines | Z-axis) |
| Line sag | (increase in barometric pressure) |
| Wire tension | (decrease in barometric pressure) |
| Core break | (increase in frequency of movement on the X-axis) |
| Transformer | (jolted movement for failure or vibration as a precursor to |
| | failure, both seen on accelerometer) |
| Vegetation | (consistent small movement, although larger |
| Interference | than status quo, on the Y-axis) |
| Fire in | (ambient temperature change over time, or ambient |
| vicinity | temperature increasing at an accelerated rate) |
| Loose bolt | (likely vibration, seen via accelerometer) |
| Insulator | (z-axis jolting activity, instant change in barometric |
| slippage | pressure) |
| Phase to | (barometric pressure increase followed by significant |
| Phase | movement in Y & Z axis) |
| Overpowering | (line temp increase, ambient temp increase, |
| line | barometric pressure increase) |
| Fire in | (line temp increase, ambient temperature increase) |
| vicinity | |
| Corrosion | (line temp increase) |

As the system 100 obtains more sensor data, it is possible to adjust the thresholds to thereby revise the operational profile in any of the sensor tags 110. In one embodiment, the system 100 uses machine learning to find normal operating ranges for the various sensors and develop new thresholds that can be individualized to each sensor tag 110. The machine learning is typically performed by the system controller 133 illustrated in FIGS. 1 and 2. As part of the machine learning process, the system 100 receives all data generated by each sensor tag 110 and determines which data values actually initiated and/or resulted in actionable items, such as powerline repairs, power outages, and the like.

Other data generated by the sensor tags 110 may reflect normal operation. For example, it is known the powerlines always have a certain amount of sway due to the wind. The system 100 uses machine learning to determine, over time, what amount of sway is “normal” for a particular sensor tag 110. This knowledge can be used to adjust the thresholds for the barometer 152 and accelerometers 156. Similarly, the machine learning can track ambient temperature ranges as well as powerline temperature ranges over time to determine normal operational values for powerline temperature. This knowledge can be used to adjust the thresholds for the temperature sensors 154. Data from the accelerometers 156 is also analyzed as part of the machine learning process to determine powerline movements that are associated with normal activity and those that are related to abnormal operating conditions.

The machine learning uses sensor data from nearby sensor tags 110 as well as external factors (e.g., earthquakes), and environmental data (e.g., temperature, wind, precipitation, etc.) to determine whether the data from a particular sensor tag 110 is valid and whether thresholds should be adjusted up or down for any particular measurement parameter. For example, a particular sensor tag 110 may report changes in the powerline height. However, nearby sensor tags 110 may also be reporting similar movements thus indicating that wind may be causing all sensor tags to experience similar conditions that are not alarm conditions and do not require a change in thresholds. In addition, weather reports can indicate higher than normal winds that can account for the height changes.

As previously discussed, the system 100 is capable of adjusting thresholds to compensate for seasonal variations, such as hot summer vs. cold winter, rainy season vs. dry season, and the like, for any particular geographic location.

As a result of the machine learning, the system 100 can develop new threshold values to replace or supplement initial threshold values that may be programmed into the sensor tags 110 at install. As described above, the system 100 includes bidirectional communications between the backhaul communications node 112 and each of the sensor tags 110 with which it communicates. The system 100 also includes bidirectional communications between the system controller 133 and the backhaul communications node 112. As new threshold data is developed as a result of the machine learning, the system controller 133 can download the new profile data to each sensor tag 110 via the respective backhaul communications node 112.

The system 100 advantageously provides automated profile updates that are the result of machine learning. Those skilled in the art will appreciate that even sensor tags 110 that are in close geographical proximity to each other may have different profiles. For example, the sensor tags 110 on one powerline segment may be an area with dense vegetation or trees while the sensor tags 110 on the next powerline segment may be in a clear area. The same amount of movement of the powerlines may be no problem in the powerline segment in the clear area, but result in an abnormal condition in the powerline segment near vegetation or trees. The profiles developed by machine learning may be different for these different powerlines segments. Thus, the system 100 adapts to normal operating conditions throughout the power transmission and distribution systems to minimize false alarms, but detect any abnormal operating conditions.

The system 100 can store profiles for each sensor tag 110 in the system controller. These profiles can be used when a particular sensor tag 110 must be replaced. The replacement sensor tag 110 can be initially configured with the profile data from the sensor tag 110 that is being replaced. Similarly, new sensor tags 110 can be initially programmed with profile data based on similarities in the environmental conditions with existing sensor tags. For example, stored profile data can be categorized by a number of different parameters, such as installation type (transmission system vs. distribution system, line size, line tension, line temperature, operational voltage, current, and the like), region of the country (e.g., hot southern region vs. cool northern region), geologic conditions (e.g., mountains, forests, open desert, and the like), local conditions (e.g., trees, vegetation, building, and the like) and other factors known to those skilled in the art. This approach permits a new sensor tag 110 to be initially programmed with a profile whose thresholds more closely match expected operating conditions. With the machine learning process described above, the new sensor tag 110 will quickly reach a final set of threshold values individualized for that particular sensor tag.

The system controller 133 also tracks changes in the profile over time to develop a historic operational profile. Changes in the historic profile can be used to determine whether the changes are indicative of undesirable changes in the infrastructure. For example, an increase in powerline sag over a period of time may indicate weakened strength of the powerlines themselves.

The foregoing described embodiments depict different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality.

While particular embodiments of the present invention have been shown and described, it will be obvious to those skilled in the art that, based upon the teachings herein, changes and modifications may be made without departing from this invention and its broader aspects and, therefore, the appended claims are to encompass within their scope all such changes and modifications as are within the true spirit and scope of this invention. Furthermore, it is to be understood that the invention is solely defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Accordingly, the invention is not limited except as by the appended claims.

The invention claimed is:

1. A system for monitoring a plurality of electrical powerlines supported by a plurality of electrical powerline support structures, the system comprising:
a plurality of sensor tags attachable to electrical powerlines, each of the plurality of sensor tags comprising:
a plurality of sensors configured to measure a position and movement associated with the electrical powerline to which the sensor tag is attached and to generate sensor data related thereto;
a battery to provide electrical power to the sensor tag;
a processor configured to control operation of the sensor tag, the processor coupled to the plurality of sensors to receive the sensor data therefrom; and
a wireless transceiver controlled by the processor and configured to transmit the sensor data; and
a backhaul communications node configured for wireless communication with the wireless transceiver in each of the respective sensor tags to receive the transmitted sensor data and to provide the sensor data to a designated network location.

2. The system of claim 1 wherein the plurality of sensors includes an accelerometer to detect motion of the electrical powerline to which the sensor tag is attached.

3. The system of claim 1 wherein the plurality of sensors includes a three axis accelerometer to detect motion of the electrical powerline to which the sensor tag is attached in three dimensions.

4. The system of claim 1 wherein the plurality of sensors includes a temperature sensor configured to measure a temperature of the electrical powerline to which the sensor tag is attached.

5. The system of claim 1 wherein the plurality of sensors includes a temperature sensor configured to measure an environmental temperature.

6. The system of claim 1 wherein the plurality of sensors includes a barometer configured to measure an environmental pressure and thereby indicate a height of the electrical powerline to which the sensor tag is attached above ground.

7. The system of claim 1 wherein the plurality of sensors includes a hygrometer configured to measure an environmental humidity.

8. The system of claim 1 wherein the battery provides electrical power to the sensor tag for a plurality of years.

9. The system of claim 1 wherein the plurality of electrical powerline support structures comprises transmission towers as part of a power transmission system.

10. The system of claim 9, further comprising a tower sensor tag attachable to the at least one transmission tower to measure a position and movement associated with the transmission tower to which the tower sensor tag is attached and to generate sensor data related thereto.

11. The system of claim 1 wherein the plurality of electrical powerline support structures comprises power poles as part of a power distribution system.

12. The system of claim 11, further comprising a pole sensor tag attachable to the at least one power pole to measure a position and movement associated with the power pole to which the pole sensor tag is attached and to generate sensor data related thereto.

13. The system of claim 1, further comprising a cellular transceiver in the backhaul communications node wherein the backhaul communications node is configured to provide the sensor data to the designated network location via a cellular link using the cellular transceiver.

14. The system of claim 1, further comprising a satellite transceiver in the backhaul communications node wherein the backhaul communications node is configured to provide the sensor data to the designated network location via a satellite link using the satellite transceiver.

15. The system of claim 1 wherein each of the plurality of sensors has a range of initial sensor data values predetermined to be normal values, the range of normal sensor data values being provided to the processor as initial profile data for each of the plurality of sensors.

16. The system of claim 15, further comprising a central controller, at the designated network location, configured to collect sensor data for each of the plurality of sensors over a period of time and to revise the profile data for any of the plurality of sensors when the collected data indicates an updated range of normal sensor data values different from the initial profile data.

17. The system of claim 16 wherein the processor instructs the wireless transceiver to transmit the sensor data only when the sensor data is outside the range of sensor data values in the profile data.

18. The system of claim 17 wherein the processor periodically instructs the wireless transceiver to transmit the sensor data irrespective of the range of sensor data values in the profile data.

19. A system for monitoring an electrical powerline supported by a plurality of electrical powerline support structures, the system comprising:
a sensor tag attachable to the electrical powerline;
a plurality of sensors configured to measure a position and movement associated with the electrical powerline and to generate sensor data related thereto;
a battery to provide electrical power to the sensor tag;
a processor configured to control operation of the sensor tag, the processor coupled to the plurality of sensors to receive the sensor data therefrom; and
a wireless transceiver controlled by the processor and configured to transmit the sensor data.

20. The system of claim 19 wherein the plurality of sensors includes an accelerometer to detect motion of the electrical powerline to which the sensor tag is attached.

21. The system of claim 19 wherein the plurality of sensors includes a temperature sensor configured to measure a temperature of the electrical powerline to which the sensor tag is attached.

22. The system of claim 19 wherein the plurality of sensors includes a temperature sensor configured to measure an environmental temperature.

23. The system of claim 19 wherein the plurality of sensors includes a barometer configured to measure an environmental pressure and thereby indicate a height of the electrical powerline to which the sensor tag is attached above ground.

24. The system of claim 19 wherein the plurality of sensors includes a hygrometer configured to measure an environmental humidity.

25. The system of claim 19 wherein the wireless transceiver is a satellite transceiver configured to provide the sensor data to a designated network location via a satellite link using the satellite transceiver.

26. The system of claim 19 wherein the wireless transceiver is a short-range transceiver, the system further comprising a backhaul communications node configured for wireless communication with the short-range wireless transceiver to receive the transmitted sensor data and to provide the sensor data to the designated network location.

27. The system of claim 26, further comprising a cellular transceiver in the backhaul communications node wherein the backhaul communications node is configured to provide the sensor data to the designated network location via a cellular link using the cellular transceiver.

28. The system of claim 26, further comprising a satellite transceiver in the backhaul communications node wherein the backhaul communications node is configured to provide the sensor data to the designated network location via a satellite link using the satellite transceiver.

29. The system of claim 19, further comprising an electrical powerline support structure sensor tag attachable to at least one electrical powerline support structure to measure a position and movement associated with the electrical powerline support structure to which the electrical powerline support structure sensor tag is attached and to generate sensor data related thereto.

30. The system of claim 19 wherein each of the plurality of sensors has a range of initial sensor data values predetermined to be normal values, the range of normal sensor data values being provided to the processor as initial profile data for each of the plurality of sensors.

31. The system of claim 30, further comprising a central controller configured to collect sensor data for each of the plurality of sensors over a period of time and to revise the profile data for any of the plurality of sensors when the collected data indicates an updated range of normal sensor data values different from the initial profile data.

32. The system of claim 31 wherein the processor instructs the wireless transceiver to transmit the sensor data only when the sensor data is outside the range of sensor data values in the profile data.

33. The system of claim 32 wherein the processor periodically instructs the wireless transceiver to transmit the sensor data irrespective of the range of sensor data values in the profile data.

34. A method for monitoring an electrical powerline supported by a plurality of electrical powerline support structures, the method comprising:
attaching a sensor tag to the electrical powerline;
a plurality of sensors in the sensor tag measuring a position and movement of the electrical powerline and generating sensor data related thereto;
a processor receiving the sensor data from the plurality of sensors; and
a wireless transceiver transmitting the sensor data under operational control of the processor.

35. The method of claim 34 wherein measuring movement of the electrical powerline is performed by an accelerometer.

36. The method of claim 34 wherein measuring the position of the electrical powerline comprises a barometer measuring an environmental pressure to thereby indicate a height of the electrical powerline above ground.

37. The method of claim 34, further comprising measuring a temperature of the electrical powerline using a temperature sensor.

38. The method of claim 34, further comprising measuring an environmental temperature using a temperature sensor.

39. The method of claim 34, further comprising measuring an environmental humidity using a hygrometer.

40. The method of claim 34 wherein transmitting the sensor data comprises transmitting the sensor data to a designated network location via a satellite link using a satellite transceiver.

41. The method of claim 34 wherein transmitting the sensor data comprises transmitting the sensor data to a backhaul communications node using a short-range transceiver, the method further comprising the backhaul communications node receiving the transmitted sensor data and providing the sensor data to a designated network location.

42. The method of claim 41 wherein providing the sensor data to the designated network location comprises the backhaul communications node transmitting the sensor data to the designated network location via a cellular link using a cellular transceiver.

43. The method of claim 41 wherein providing the sensor data to the designated network location comprises the backhaul communications node transmitting the sensor data to the designated network location via a satellite link using a satellite transceiver.

44. The method of claim 34, further comprising:
attaching a sensor tag to at least one electrical powerline support structure; and
the plurality of sensors in the sensor tag measuring a position and movement of the electrical powerline support structure to which the electrical powerline support structure sensor tag is attached and generating sensor data related thereto;
the processor receiving the sensor data from the plurality of sensors; and
the wireless transceiver transmitting the sensor data under operational control of the processor.

45. The method of claim 34, further comprising assigning each of the plurality of sensors a range of initial sensor data values determined to be normal values, the range of normal sensor data values being provided to the processor as initial profile data for each of the plurality of sensors.

46. The method of claim 45, further comprising:
collecting sensor data for each of the plurality of sensors over a period of time; and
revising the profile data for any of the plurality of sensors when the collected data indicates an updated range of normal sensor data values different from the initial profile data.

47. The method of claim 46, further comprising the processor instructing the wireless transceiver to transmit the sensor data only when the sensor data is outside the range of sensor data values in the profile data.

48. The method of claim 47, further comprising the processor periodically instructing the wireless transceiver to transmit the sensor data irrespective of the range of sensor data values in the profile data.
